(19) United States
(12) Patent Application Publication
(10) Pub. No.: US 2023/0003936 A1
(43) Pub. Date: Jan. 5, 2023

(54) LIDAR WITH PLASMONIC ON-CHIP LIGHT GENERATION

(71) Applicant: Seagate Technology LLC, Fremont, CA (US)

(72) Inventor: Aditya Jain, Minneapolis, MN (US)

(21) Appl. No.: 17/849,967

(22) Filed: Jun. 27, 2022

Related U.S. Application Data
(60) Provisional application No. 63/215,694, filed on Jun. 28, 2021.

(51) Int. Cl. G02B 6/12; G01S 17/66

(52) U.S. Cl. CPC G02B 6/12004; G01S 17/66; G02B 2006/12121; G02B 2006/12061; G02B 2006/12138

(57) ABSTRACT

A light detection and ranging system can employ a metal insulator metal tunnel junction positioned atop a substrate. Activation of the metal insulator metal tunnel junction by a signal from a controller can generate light via inelastic scattering. Light to be used to detect downrange targets can be combined from multiple junctions via a multimode interference combiner.

### SUMMARY

Light detection and ranging can be optimized, in various embodiments, by employing a metal insulator metal tunnel junction positioned atop a substrate. Activation of the metal insulator metal tunnel junction by a signal from a controller generates light via inelastic scattering. Light to be used to detect downrange targets can be combined from multiple junctions via a multimode interference combiner.

### BRIEF DESCRIPTION OF THE DRAWINGS

FIG. 1 is a block representation of an example environment in which assorted embodiments can be practiced.

FIG. 2 plots operational information for an example detection system configured in accordance with some embodiments.

FIGS. 3A & 3B respectively depict portions of an example detection system arranged and operated in accordance with various embodiments.

FIG. 4 depicts portions of an example detection system constructed and employed in accordance with some embodiments.

FIG. 5 depicts a block representation of portions of an example detection system employed in accordance with assorted embodiments.

FIG. 6 depicts a line representation of portions of an example detection system in which various embodiments can be conducted.

FIG. 7 depicts a block representation of portions of an example light energy source that may be utilized with in some embodiments.

FIG. 8 depicts portions of an example detection system configured in accordance with assorted embodiments.

FIG. 9 depicts portions of an example light detection and ranging system arranged and employed in accordance with various embodiments.

### DETAILED DESCRIPTION

Various embodiments of the present disclosure are generally directed to optimization of an active light detection system.

Advancements in computing capabilities have corresponded with smaller physical form factors that allow intelligent systems to be implemented into a diverse variety of environments. Such intelligent systems can complement, or replace, manual operation, such as with the driving of a vehicle or flying a drone. The detection and ranging of stationary and/or moving objects with radio or sound waves can provide relatively accurate identification of size, shape, and distance. However, the use of radio waves (300 GHz-3 kHz) and/or sound waves (20 kHZ-200 kHz) can be significantly slower than light waves (430-750 Terahertz), which can limit the capability of object detection and ranging while moving.

The advent of light detection and ranging (LiDAR) systems employ light waves that propagate at the speed of light to identify the size, shape, location, and movement of objects with the aid of intelligent computing systems. The ability to utilize multiple light frequencies and/or beams concurrently allows LiDAR systems to provide robust volumes of information about objects in a multitude of environmental conditions, such as rain, snow, wind, and darkness. Yet, current LiDAR systems can suffer from inefficiencies and inaccuracies during operation that jeopardize object identification as well as the execution of actions in response to gathered object information. Hence, embodiments are directed to structural and functional optimization of light detection and ranging systems to provide increased reliability, accuracy, safety, and efficiency for object information gathering.

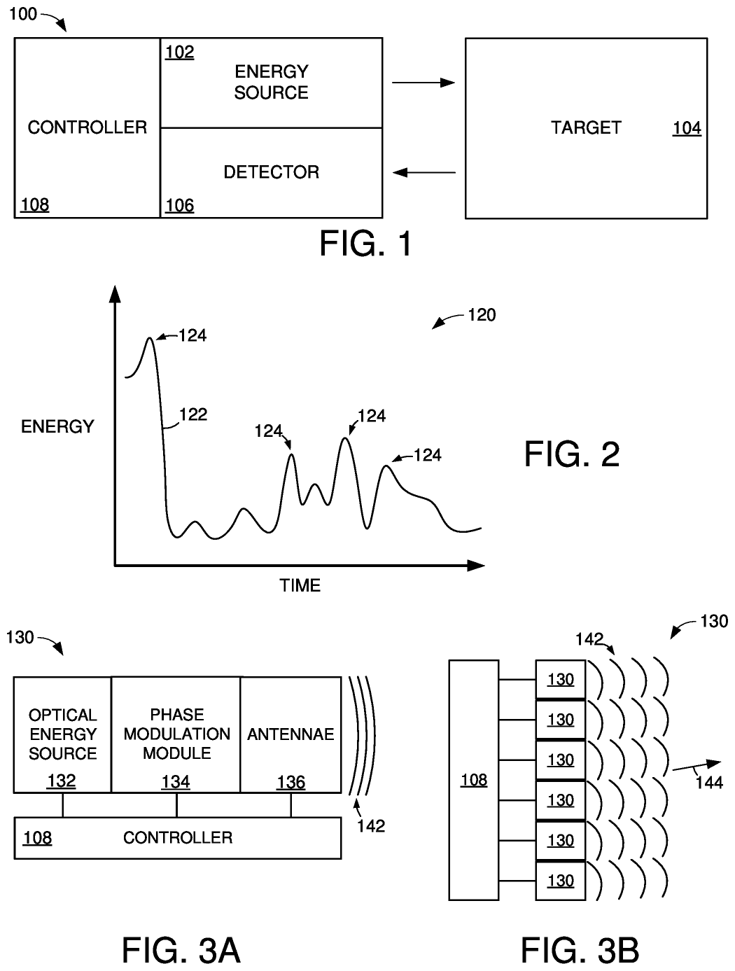

FIG. 1 depicts a block representation of portions of an example object detection environment 100 in which assorted embodiments can be practiced. One or more energy sources 102, such as a laser or other optical emitter, can produce photons that travel at the speed of light towards at least one target 104 object. The photons bounce off the target 104 and are received by one or more detectors 106. An intelligent controller 108, such as a microprocessor or other programmable circuitry, can translate the detection of returned photons into information about the target 104, such as size and shape.

The use of one or more energy sources 102 can emit photons over time that allow the controller 108 to track an object and identify the target's distance, speed, velocity, and direction. FIG. 2 plots operational information for an example light detection and ranging system 120 that can be utilized in the environment 100 of FIG. 1. Solid line 122 conveys the volume of photons received by a detector over time. The greater the intensity of returned photons (Y axis) can be interpreted by a system controller as surfaces and distances that that can be translated into at least object size and shape.

It is contemplated that a system controller can interpret some, or all, of the collected photon information from line 122 to determine information about an object. For instance, the peaks 124 of photon intensity can be identified and used alone as part of a discrete object detection and ranging protocol. A controller, in other embodiments, can utilize the entirety of photon information from line 122 as part of a full waveform object detection and ranging protocol. Regardless of how collected photon information is processed by a controller, the information can serve to locate and identify objects and surfaces in space in front of the light energy source.

FIGS. 3A & 3B respectively depict portions of an example light detection assembly 130 that can be utilized in a light detection and ranging system 140 in accordance with various embodiments. In the block representation of FIG. 3A, the light detection assembly 130 consists of an optical energy source 132 coupled to a phase modulation module 134 and an antennae 136 to form a solid-state light emitter and receiver. Operation of the phase modulation module 134 can direct beams of optical energy in selected directions relative to the antennae 136, which allows the single assembly 130 to stream one or more light energy beams in different directions over time.

FIG. 3B conveys an example optical phase array (OPA) system 140 that employs multiple light detection assemblies 130 to concurrently emit separate optical energy beams 142 to collect information about any downrange targets 104. It is contemplated that the entire system 140 is physically present on a single system on chip (SOC), such as a silicon substrate. The collective assemblies 130 can be connected to one or more controllers 108 that direct operation of the light energy emission and target identification in response to detected return photons. The controller 108, for example, can direct the steering of light energy beams 142 to a particular direction 144, such as a direction that is non-normal to the antennae 138, like 45°.

The use of the solid-state OPA system 140 can provide a relatively small physical form factor and fast operation, but can be plagued by interference and complex processing that jeopardizes accurate target 104 detection. For instance, return photons from different beams 142 may cancel, or alter, one another and result in an inaccurate target detection. Another non-limiting issue with the OPA system 140 stems from the speed at which different beam 142 directions can be executed, which can restrict the practical field of view of an assembly 130 and system 140.

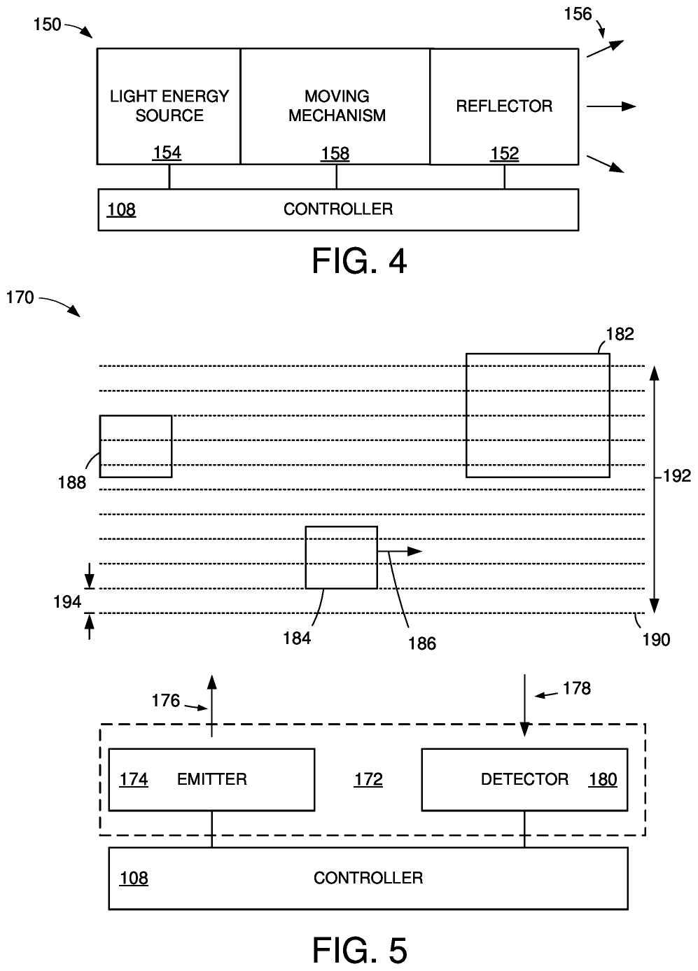

FIG. 4 depicts a block representation of a mechanical light detection and ranging system 150 that can be utilized in assorted embodiments. In contrast to the solid-state OPA system 140 in which all components are physically stationary, the mechanical system 150 employs a moving reflector 152 that distributes light energy from a source 154 downrange towards one or more targets 104. While not limiting or required, the reflector 152 can be a single plane mirror, prism, lens, or polygon with reflecting surfaces. Controlled movement of the reflector 152 and light energy source 154, as directed by the controller 108, can produce a continuous, or sporadic, emission of light beams 156 downrange.

Although the mechanical system 150 can provide relatively fast distribution of light beams 156 in different directions, the mechanism to physically move the reflector 152 can be relatively bulky and larger than the solid-state OPA system 140. The physical reflection of light energy off the reflector 152 also requires a clean environment to operate properly, which restricts the range of conditions and uses for the mechanical system 150. The mechanical system 150 further requires precise operation of the reflector 152 moving mechanism 158, which may be a motor, solenoid, or articulating material, like piezoelectric laminations.

FIG. 5 depicts a block representation of an example detection system 170 that is configured and operated in accordance with various embodiments. A light detection and ranging assembly 172 can be intelligently utilized by a controller 108 to detect at least the presence of known and unknown targets downrange. As shown, the assembly 172 employs one or more emitters 174 of light energy in the form of outward beams 176 that bounce off downrange targets and surfaces to create return photons 178 that are sensed by one or more assembly detectors 180. It is noted that the assembly 172 can be physically configured as either a solid-state OPA or mechanical system to generate light energy beams 172 capable of being detected with the return photons 178.

Through the return photons 178, the controller 108 can identify assorted objects positioned downrange from the assembly 172. The non-limiting embodiment of FIG. 5 illustrates how a first target 182 can be identified for size, shape, and stationary arrangement while a second target 184 is identified for size, shape, and moving direction, as conveyed by solid arrow 186. The controller 108 may further identify at least the size and shape of a third target 188 without determining if the target 188 is moving.

While identifying targets 182/184/188 can be carried out through the accumulation of return photon 178 information, such as intensity and time since emission, it is contemplated that the emitter(s) 174 employed in the assembly 172 stream light energy beams 176 in a single plane, which corresponds with a planar identification of reflected target surfaces, as identified by segmented lines 190. By utilizing different emitters 174 oriented to different downrange planes, or by moving a single emitter 174 to different downrange planes, the controller 108 can compile information about a selected range 192 of the assembly's field of view. That is, the controller 108 can translate a number of different planar return photons 178 into an image of what targets, objects, and reflecting surfaces are downrange, within the selected field of view 192, by accumulating and correlating return photon 178 information.

The light detection and ranging assembly 172 may be configured to emit light beams 176 in any orientation, such as in polygon regions, circular regions, or random vectors, but various embodiments utilize either vertically or horizontally single planes of beam 176 dispersion to identify downrange targets 182/184/188. The collection and processing of return photons 178 into an identification of downrange targets can take time, particularly the more planes 190 of return photons 178 are utilized. To save time associated with moving emitters 174, detecting large volumes of return photons 178, and processing photons 178 into downrange targets 182/184/188, the controller 108 can select a planar resolution 194, characterized as the separation between adjacent planes 190 of light beams 176.

In other words, the controller 108 can execute a particular downrange resolution 194 for separate emitted beam 176 patterns to balance the time associated with collecting return photons 178 and the density of information about a downrange target 182/184/188. As a comparison, tighter resolution 194 provides more target information, which can aid in the identification of at least the size, shape, and movement of a target, but bigger resolution 194 (larger distance between planes) can be conducted more quickly. Hence, assorted embodiments are directed to selecting an optimal light beam 176 emission resolution to balance between accuracy and latency of downrange target detection.

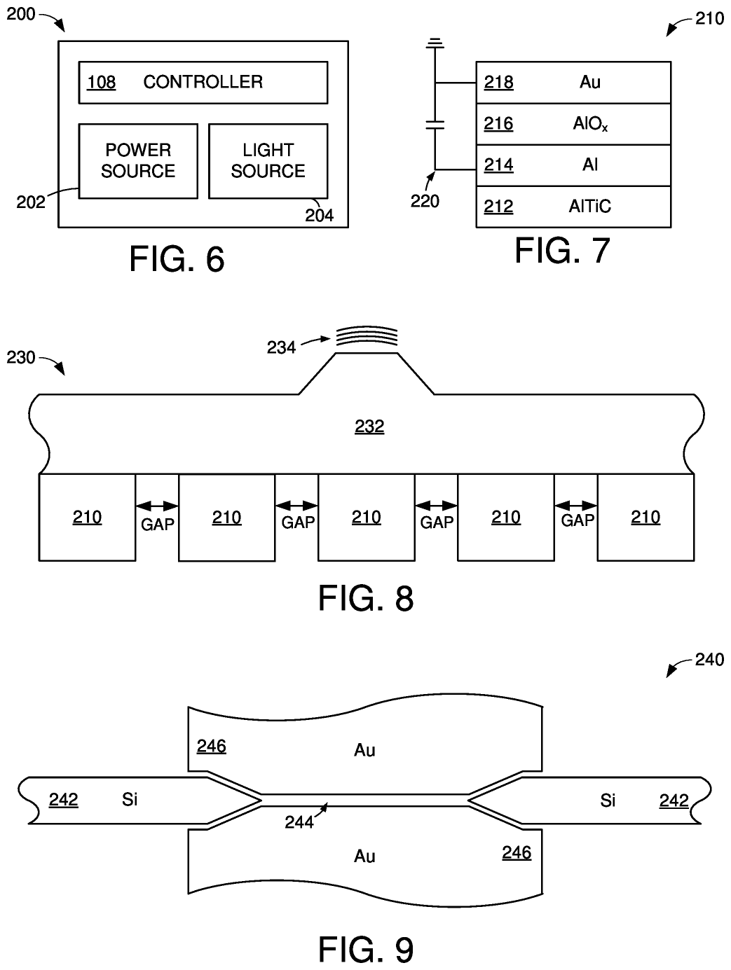

FIG. 6 depicts portions of an example light detection and ranging system 200 that packages components to be capable of deployment in a diverse variety of practical locations, such as vehicles, flying devices, and robotics. A location controller 108 can direct delivery of electrical power 202 to a light generation source 204 where light energy is created and transmitted to detect downstream targets. While not limiting, the generation of light energy from the source 204 located on a single chip 206 with other system 200 components can reduce the overall package size while improving the interchangeability after deployment.

FIG. 7 depicts a block representation of an example tunnel junction 210 that can be employed in an on-chip light generation source portion of a light detection and ranging system in accordance with some embodiments. An insulating base layer 212 provides a rigid foundation for a first metal layer 214, an insulator layer 216, and a second metal layer 218. Connection of the respective metal layers 214/218 to an electric current via activation circuitry 220 can produce plasmonic energy that is emitted downrange as light. It is noted that the material construction shown in FIG. 7 is not required or limiting, but can provide efficient energy generation for light detection and ranging purposes.

In some light energy sources that are made from direct bandgap semiconductor materials, such as GaAs, InGaAsP, InGaAs, InP, and GaSn, expense can be inhibitive. Light sources from cheap metals may be more desirable, but provide less efficiency. Accordingly, various embodiments use a metal insulator metal tunnel junction 210 to generate light via inelastic scattering, which can provide power output of approximately 1-10 microwatts from a single tunnel junction.

FIG. 8 depicts portions of an example light detection and ranging system 230 that concurrently employs a number of tunnel junctions 210 to increase the total amount of power available to detect and range targets. As shown, a multimode interference (MMI) combiner 232 is coupled to a number of tunnel junctions 210 and serves to harness the power of the constituent junctions 210 into a light energy beam 234. It is contemplated that multiple separate combiners 232 can be concurrently, or sequentially, employed to send one or more light energy beams 234 downrange.

FIG. 9 depicts a line representation of portions of an example mode converter 240 portion of a light detection and ranging system. Some operational embodiments utilize the converter 240 to translate plasmonic energy produced by a tunnel junction 210 into photonic energy that can be emitted downrange as a light beam capable of detecting targets. The physical arrangement of the converter 240 can be tuned to provide customized photonic energy generation. For instance, the size, position, and air gap surrounding tapered nodes 242 can be altered, along with the waveguide portion 244 to provide predetermined conversion of plasmonic energy to photonic energy.

The converter 240 may be constructed of any materials, but is configured with gold layers 246 and silicon nodes 242, as illustrated, to create light beams. It is contemplated that one or more converters 240 are arranged with one or more combiners 232 to create one or more concentrated light beams 232. For instance, 1000 junctions can provide a combined power of 1-10 mW. Other embodiments consist of a tunnel junction on AlTiC wafer with a plasmonic-to-photonic converter 240 and a Nx1 Al₂O₃ plasmonic combiner.

It is to be understood that even though numerous characteristics of various embodiments of the present disclosure have been set forth in the foregoing description, together with details of the structure and function of various embodiments, this detailed description is illustrative only, and changes may be made in detail, especially in matters of structure and arrangements of parts within the principles of the present technology to the full extent indicated by the broad general meaning of the terms in which the appended claims are expressed. For example, the particular elements may vary depending on the particular application without departing from the spirit and scope of the present disclosure.

What is claimed is:

1. An apparatus comprising a tunnel junction connected to an electrical source and coupled to a converter, the converter configured to generate a photonic energy beam in response to activation of the tunnel junction.

2. The apparatus of claim 1, wherein the tunnel junction consists of a metal-insulator-metal lamination.

3. The apparatus of claim 1, wherein the tunnel junction consists of an AlOₓ layer positioned between and contacting a first metal layer and a second metal layer.

4. The apparatus of claim 3, wherein the first metal layer is aluminum.

5. The apparatus of claim 3, wherein the second metal layer is gold.

6. The apparatus of claim 1 wherein the tunnel junction is positioned atop a rigid substrate.

7. The apparatus of claim 1, wherein the converter consists of at least one node separated from metal layers by an air gap.

8. The apparatus of claim 7, wherein the at least one node comprises silicon.

9. The apparatus of claim 7, wherein the metal layers are each respectively constructed of gold.

10. The apparatus of claim 7, wherein the metal layers are separated to form a waveguide.

11. A method comprising:
connecting a tunnel junction to an electrical source, the tunnel junction coupled to a converter;
generating plasmonic energy with the tunnel junction in response to activation of the electrical source;
converting the plasmonic energy to photonic energy with the converter; and
sending the photonic energy downrange as a detection beam.

12. The method of claim 11, wherein multiple tunnel junctions are concurrently activated to create the plasmonic energy, each tunnel junction coupled to the converter.

13. The method of claim 11, wherein the photonic energy is concentrated in a combiner to form the detection beam.

14. The method of claim 11, wherein the detection beam is employed to detect a downrange target as part of a light detection and ranging system.

15. The method of claim 11, wherein the tunnel junction is activated by a signal from a controller.

16. The method of claim 11, wherein the tunnel junction and converter are positioned on a common chip.

17. The method of claim 11, wherein the detection beam employs inelastic scattering to detect at least one target located downrange of the converter.
